(19) United States
(12) Patent Application Publication
(10) Pub. No.: US 2025/0327961 A1
(43) Pub. Date: Oct. 23, 2025

(54) POLARIZING PLATE AND OPTICAL DISPLAY APPARATUS

(71) Applicant: SAMSUNG SDI CO., LTD., Yongin-si (KR)

(72) Inventors: Young Jong KIM, Suwon-si (KR); Tae Hyun LEE, Suwon-si (KR); Mi Ran SEO, Suwon-si (KR); Han Joo CHOI, Suwon-si (KR); Woo Jin JEONG, Suwon-si (KR); Il Jin KIM, Suwon-si (KR)

(21) Appl. No.: 19/182,322

(22) Filed: Apr. 17, 2025

(30) Foreign Application Priority Data
Apr. 19, 2024 (KR) 10-2024-0052668

(51) Int. Cl. G02B 5/30

(52) U.S. Cl. CPC G02B 5/3091; G02B 5/3016; G02B 5/305

(57) ABSTRACT

A polarizing plate and an optical display apparatus are disclosed. The polarizing plate includes: a polarizer; and a first bonding layer and a first retardation layer sequentially stacked on a lower surface of the polarizer. The first retardation layer has a light transmittance of 1.0% or less in the UVA wavelength range. The first bonding layer includes a cured product of a non-(meth)acrylic composition including a curable compound and a photoinitiator, and the curable compound includes an epoxy compound, the epoxy compound including a mixture of a bifunctional alicyclic epoxy compound, a bifunctional aromatic epoxy compound, and a bifunctional aliphatic epoxy compound. The photoinitiator includes a mixture of an iodonium-based photo-acid generator and an anthracene-based photosensitizer, the anthracene-based photosensitizer being present in an amount of 0.5 parts by weight or more relative to 100 parts by weight of the curable compound.

### CROSS-REFERENCE TO RELATED APPLICATION

The present application claims priority to and the benefit of Korean Patent Application No. 10-2024-0052668, filed on Apr. 19, 2024, in the Korean Intellectual Property Office, the entire content of which is incorporated herein by reference.

### BACKGROUND

### 1. Field

One or more embodiments of the present disclosure are directed toward a polarizing plate and an optical display apparatus.

### 2. Description of the Related Art

A light emitting diode display, such as an OLED and/or the like, does not necessarily require a polarizing plate. However, because the light emitting diode display may experience deterioration in visibility and/or contrast caused by reflection of external light due to exposure of electrodes, the light emitting diode display may be provided with an antireflection polarizing plate on a panel thereof. A circular polarizing plate composed of a polarizer and a retardation layer is suitable as the antireflection polarizing plate. The retardation layer may be formed by stretching a resin, however, if the retardation layer is a liquid crystal retardation layer, a reduction in thickness of the polarizing plate may also be achieved.

The liquid crystal retardation layer may be bonded to the polarizer via a bonding layer. It is desirable that the liquid crystal retardation layer is bonded to the polarizer with suitably high peel strength. Moreover, it is desirable that the liquid crystal retardation layer and/or an optical display panel do not suffer from (e.g., are not substantially affected by) color change and/or corrosion of a substrate by iodine eluted from the polarizer after the polarizing plate is left under high temperature/humidity conditions for a long period of time. SUMMARY

One or more aspects of embodiments of the present disclosure are directed toward a polarizing plate that sufficiently or suitably prevents or reduces penetration of iodine eluted from a polarizer into a retardation layer after the polarizing plate is left under high temperature/humidity conditions for a relatively long period of time.

One or more other aspects of embodiments of the present disclosure are directed toward a polarizing plate having suitably high peel strength between a polarizer and a retardation layer having a light transmittance of 1.0% or less in the UVA wavelength range, and/or between a protective layer and the retardation layer.

In accordance with one or more embodiments of the present disclosure, there is provided a polarizing plate.

The polarizing plate includes: a polarizer; and a first bonding layer and a first retardation layer sequentially stacked on a lower surface of the polarizer, wherein the first retardation layer has a light transmittance of 1.0% or less in the UVA wavelength range, wherein the first bonding layer includes a cured product of a non-(meth)acrylic composition including a curable compound and a photoinitiator, wherein the curable compound includes an epoxy compound, the epoxy compound including a mixture of a bifunctional alicyclic epoxy compound, a bifunctional aromatic epoxy compound, and a bifunctional aliphatic epoxy compound, and wherein the photoinitiator includes a mixture of an iodonium-based photo-acid generator and an anthracene-based photosensitizer, the anthracene-based photosensitizer being present in an amount of 0.5 parts by weight or more relative to 100 parts by weight of the curable compound.

In accordance with one or more embodiments of the present disclosure, there is provided an optical display apparatus.

The optical display apparatus includes the polarizing plate according to the present disclosure.

Embodiments of the present disclosure provide a polarizing plate that sufficiently or suitably prevents or reduces penetration of iodine eluted from a polarizer into a retardation layer after the polarizing plate is left under high temperature/humidity conditions for a relatively long period of time.

Embodiments of the present disclosure provide a polarizing plate having suitably high peel strength between a polarizer and a retardation layer having a light transmittance of 1.0% or less in the UVA wavelength range, and/or between a protective layer and the retardation layer.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a cross-sectional view of a polarizing plate according to one or more embodiments of the present disclosure.

FIG. 2 is a cross-sectional view of a polarizing plate according to one or more other embodiments of the present disclosure.

FIG. 3 is a schematic diagram illustrating evaluation of iodine elution from a polarizer (disappearance of iodine color), according to one or more embodiments of the present disclosure.

### DETAILED DESCRIPTION

Hereinafter, example embodiments of the present disclosure will be described in more detail with reference to the accompanying drawings to facilitate practice by a person having ordinary knowledge in the art. It should be understood, however, that the present disclosure may be embodied in different ways and is not limited to the following embodiments. In the drawings, portions irrelevant to the description will not be provided for clarity and like components will be denoted by like reference numerals throughout the specification and drawings. It should be understood that lengths, sizes, and/or the like of components in the drawings are set for illustration (e.g., may be exaggerated) and the present disclosure is not limited thereto.

Herein, spatially relative terms, such as “beneath,” “below,” “lower,” “above,” “upper,” “bottom,” “top” and the like, are defined with reference to the accompanying drawings. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, it will be understood that the term “upper surface” can be used interchangeably with the term “lower surface”. The device may be otherwise oriented (rotated 90 degrees or at other orientations), and the spatially relative descriptors used herein should be interpreted accordingly.

The terminology used herein is for the purpose of describing example embodiments and is not intended to limit the present disclosure. As used herein, the singular forms, “a”, “an”, and “the” are intended to include the plural forms as well, unless the context clearly indicates otherwise.

It will be understood that, although the terms first, second, etc. may be used herein to describe various elements, these elements should not be limited by these terms. These terms are only used to distinguish one element from another element. Thus, a first element could be termed a second element without departing from the teachings of the present invention. Similarly, a second element could be termed a first element.

It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items. Further, the use of “may” when describing embodiments of the present disclosure refers to “one or more embodiments of the present disclosure”.

It will be understood that when an element is referred to as being “on,” “connected to,” or “coupled to” another element, it may be directly on, connected, or coupled to the other element or one or more intervening elements may also be present. When an element is referred to as being “directly on,” “directly connected to,” or “directly coupled to” another element, there are no intervening elements present.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic device and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Herein, “in-plane retardation Re” and “out-of-plane retardation Rth” are represented by Equations A and B, respectively:

$$Re = ( nx - ny ) \times d , \qquad ( A )$$

$$Rth = ( ( nx + ny ) / 2 - nz ) \times d , \qquad ( B )$$

where nx and ny are the in-plane indexes of refraction of an optical device, as measured in the slow axis direction and the fast axis direction thereof at a measurement wavelength, respectively; nz is a refractive index as measured in the direction normal to the plane of the optical device; and d is the thickness (unit: nm) of the optical device.

Herein, “short-wavelength dispersion” refers to Re(450)/Re(550) and “long-wavelength dispersion” refers to Re(650)/Re(550), where Re(450), Re(550), and Re(650) refer to in-plane retardations (Re) of the optical device at wavelengths of 450 nm, 550 nm, and 650 nm, respectively.

Herein, “negative dispersion” refers to Re(450)<Re(550)<Re(650).

Herein, “UVA wavelength range” refers to a wavelength range of 320 nm to 390 nm.

Herein, “degree of polarization” refers to a value measured at a wavelength of 400 nm to 800 nm, for example, at a wavelength of 550 nm.

Herein, “(meth)acryl” refers to acryl and/or methacryl.

As used herein to represent a specific numerical range, “X to Y” refers to “greater than or equal to X and less than or equal to Y (X≤ and ≤Y)”.

A polarizing plate according to the present disclosure can sufficiently or suitably prevent or reduce penetration of decolorized and/or eluted iodine from a polarizer into a retardation layer even after being left under high temperature/humidity conditions for a long period of time. The polarizing plate according to the present disclosure has suitably high peel strength between a polarizer and a retardation layer having a light transmittance of 1.0% or less in the UVA wavelength range, and/or between a protective layer and the retardation layer.

The polarizing plate according to one or more embodiments may be used as an antireflection polarizing plate in a light emitting diode display, such as an organic light emitting diode display and/or the like. The polarizing plate according to the embodiments may be used in a flexible, foldable and/or bendable optical display apparatus requiring (or desiring) flexural reliability.

In one or more embodiments, the polarizing plate includes: a polarizer; and a first bonding layer and a first retardation layer (e.g., a first liquid crystal retardation layer) sequentially stacked on a lower surface of the polarizer. In one or more embodiments, the first bonding layer and the first liquid crystal retardation layer may be arranged between the polarizer and an optical display panel. In one or more embodiments, the first retardation layer may be bonded to the polarizer by the first bonding layer.

### First Retardation Layer

The first retardation layer may be arranged between the polarizer and the optical display panel and may serve to prevent or reduce reflection of external light, having passed through the polarizer, by circularly polarizing linearly polarized light emitted from the polarizer, thereby realizing an antireflection function to improve external appearance and/or screen quality.

In one or more embodiments, the first retardation layer may have an in-plane retardation of 100 nm to 220 nm, or 100 nm to 180 nm, for example, a retardation of λ/4, at a wavelength of 550 nm. Within any of these ranges, the first retardation layer can improve screen quality by reducing reflectivity to external light.

In one or more other embodiments, the first retardation layer may have an in-plane retardation of 225 nm to 350 nm, or 225 nm to 300 nm, for example, a retardation of λ/2, at a wavelength of 550 nm. Within any of these ranges, the first retardation layer can improve screen quality by reducing reflectivity to external light.

In one or more embodiments, the first retardation layer may have negative dispersion. The negative dispersion allows the polarizing plate to provide a further improved antireflection function.

The first retardation layer may have a light transmittance of 1.0% or less in the UVA wavelength range. For example, the first retardation layer may have a light transmittance of 0.0% to 0.8% in the UVA wavelength range. The light transmittance may be adjusted by (e.g., may be varied due to) materials constituting the first retardation layer, wavelength dispersion of the first retardation layer, a method of forming the first retardation layer with the materials, and/or the like.

With the first retardation layer having a light transmittance of 1.0% or less in the UVA wavelength range, the polarizing plate according to the present disclosure includes the first bonding layer that is sufficiently or suitably cured, secures suitably high peel strength between the first retardation layer and the polarizer, and can sufficiently or suitably prevent or reduce penetration of decolorized and/or eluted iodine from the polarizer into the retardation layer after the polarizing plate is left under high temperature/humidity conditions for a long period of time.

In one or more embodiments, the first retardation layer is a liquid crystal retardation layer and may be formed of a composition including a liquid crystalline compound containing at least one selected from among an aromatic functional group, an alicyclic functional group, and an aliphatic functional group. The liquid crystalline compound may be a polymer, an oligomer, or a monomer that contains a unit containing an aromatic ring and a polymerizable functional group that can impart liquid crystallinity. The polymerizable functional group may include a (meth)acryloyl group, an epoxy group, a vinyl ether group, and/or the like, and may be cured by heat and/or light to increase strength of the liquid crystal retardation layer.

The composition for the first retardation layer may further include suitable additives, such as leveling agents, polymerization initiators, alignment aids, heat stabilizers, lubricants, plasticizers, antistatic agents, and/or the like, which may be recognized by those skilled in the art.

The first retardation layer may be transferred to the polarizer or the protective layer from a film for the first retardation layer. The film for the first retardation layer may include a first retardation layer and a base film arranged on one surface of the first retardation layer. The film for the first retardation layer may be formed by coating the composition for the first retardation layer to a set or predetermined thickness on one surface of the base film, followed by curing the composition. The base film may be any suitable film in the art, for example, a polyethylene terephthalate film and/or a triacetylcellulose film.

The first retardation layer may further include an alignment layer on a lower surface thereof, for example, a surface opposite to the first bonding layer. When the first retardation layer is formed of liquid crystals, the alignment layer may have desirable or suitable wavelength dispersion and in-plane retardation by adjusting the degree of alignment and/or the alignment direction of the liquid crystals.

The alignment layer may be formed by coating and curing a composition for the alignment layer. According to one or more embodiments, the alignment layer may be a rubbed film formed of an organic compound, such as a polymer and/or the like, an omnidirectional deposition film of an inorganic compound, a film having micro grooves, and/or a film having a stack of LB films including an organic compound, such as tricosanoic acid and/or dioctadecylmethyl ammonium chloride, and methyl stearate. In one or more embodiments, the alignment layer may have an alignment function produced by irradiation with light. In other words, the alignment layer may exhibit alignment functionality when irradiated with light. The composition for the alignment layer may include polyimide, polyvinyl alcohol, modified polyvinyl alcohol, and/or a polymer having a polymerizable group. Alignment treatment may be performed by rubbing a surface of a polymer layer, by irradiating a photo-alignment material with polarized or non-polarized light, and/or by heating a coating of the composition for the alignment layer.

In one or more embodiments, the first retardation layer may have a thickness of 0.1 μm to 10 μm, for example, 1 μm to 5 μm. Within this range, the first retardation layer can provide desired or suitable in-plane retardation while allowing reduction in thickness of the polarizing plate.

### First Bonding Layer

The first bonding layer may bond the polarizer and/or the protective layer to the first retardation layer. The first bonding layer can sufficiently or suitably prevent or reduce penetration of decolorized and/or eluted iodine from the polarizer into the retardation layer even after the polarizing plate is left under high temperature/humidity conditions for a long period of time. In one or more embodiments, the first bonding layer can increase peel strength between the polarizer and the retardation layer having a light transmittance of 1.0% or less in the UVA wavelength range, and/or between the protective layer and the retardation layer. The polarizing plate according to the present disclosure includes a bonding layer, as the first bonding layer, which can prevent or reduce penetration of decolored and/or eluted iodine into the retardation layer while increasing peel strength between the polarizer and the retardation layer having a light transmittance of 1.0% or less in the UVA wavelength range, and/or between the protective layer and the retardation layer.

The first bonding layer may include a cured product of a non-(meth)acrylic composition that includes a curable compound and a photoinitiator, wherein the curable compound includes an epoxy compound, and the photoinitiator includes a mixture of an iodonium-based photo-acid generator and an anthracene-based photosensitizer. The epoxy compound includes a mixture of a bifunctional alicyclic epoxy compound, a bifunctional aromatic epoxy compound and a bifunctional aliphatic epoxy compound, and the anthracene-based photosensitizer is present in an amount of 0.5 parts by weight or more relative to 100 parts by weight of the curable compound.

The first bonding layer includes a cured product of a non-(meth)acrylic composition including a curable compound and a photoinitiator. The cured product may be a photo-cured product.

In one or more embodiments, the first bonding layer may include a curable compound and a photoinitiator. Here, the curable compound and the photoinitiator may be derived from the non-(meth)acrylic composition.

The composition may be a non-(meth)acrylic composition. Herein, “non-(meth)acrylic composition” refers to the composition that does not contain a (meth)acrylic component. Without being bound by any particular theory, it is believed that the first bonding layer that is formed of a composition using both (e.g., simultaneously) an epoxy compound and a (meth)acrylic compound together with the mixture of the iodonium-based photo-acid generator and the anthracene-based photosensitizer as a photoinitiator cannot sufficiently or suitably increase peel strength between the polarizer and the retardation layer having a light transmittance of 1.0% or less in the UVA wavelength range, and/or between the protective layer and the retardation layer.

The curable compound may include an epoxy compound (A), which may include the mixture of the bifunctional alicyclic epoxy compound, the bifunctional aromatic epoxy compound, and the bifunctional aliphatic epoxy compound.

In the first bonding layer, the curable compound can facilitate increase in peel strength between the polarizer (and/or protective layer) and the retardation layer having a light transmittance of 1.0% or less in the UVA wavelength range by satisfying or utilizing the composition according to the present embodiments.

Hereinafter, the curable compound will be described in more detail.

In one or more embodiments, the curable compound is a photo-curable compound and may be present in an amount of 90 wt % or more, for example, 95 wt % to 100 wt %, in the composition in terms of solid content (e.g., amount). Within any of these ranges, the curable compound can secure good or suitable improvement in bonding strength, reliability and/or compatibility of the first bonding layer.

In one or more embodiments, the mixture may be present in an amount of 95 parts by weight or more, for example, 99 parts by weight to 100 parts by weight, or 100 parts by weight, relative to 100 parts by weight of the curable compound. Within any of these ranges, the curable compound can secure good or suitable improvement in bonding strength, reliability and/or compatibility of the first bonding layer.

The epoxy compound may include the mixture of the bifunctional alicyclic epoxy compound, the bifunctional aromatic epoxy compound, and the bifunctional aliphatic epoxy compound.

A polarizing plate including a first bonding layer formed of a composition free from the bifunctional alicyclic epoxy compound can have insufficient or unsuitable bonding strength after UV curing due to an unsuitably low initial reaction rate, thus causing process defects, such as end lifting and/or the like.

A polarizing plate including a first bonding layer formed of a composition free from the bifunctional aromatic epoxy compound can have poor or unsuitable adhesion between the bonding layer and liquid crystals, causing problems of poor processability and reliability due to relatively easy peeling even by insignificant impact after curing.

A polarizing plate including a first bonding layer formed with a composition free from the bifunctional aliphatic epoxy compound may have a viscosity of 200 cP or more, which is likely to cause coating and process defects of a bonding agent.

In one or more embodiments, the bifunctional alicyclic epoxy compound, the bifunctional aromatic epoxy compound, and the bifunctional aliphatic epoxy compound may be present in a total amount of 95 parts by weight or more, for example, 99 parts by weight to 100 parts by weight, or 100 parts by weight, relative to 100 parts by weight of the epoxy compound (A). Within any of these ranges, the polarizing plate can realize (e.g., easily realize) the effects of the present disclosure.

The bifunctional alicyclic epoxy compound may include a compound containing a carbon chain between two alicyclic epoxy groups. For example, the bifunctional alicyclic epoxy compounds may include at least one selected from among 3,4-epoxycyclohexylmethyl 3,4-epoxycyclohexanecarboxylate, 1,2-epoxy-4-vinylcyclohexane, 1,2-epoxy-1-methyl-4-(1-methylethoxyethyl)cyclohexane, 4-(1,2-epoxyethyl)-1,2-epoxycyclohexane adducts of 2,2-bis(hydroxymethyl)-1-butanol, ethylene bis(3,4-epoxycyclohexanecarboxylate), oxydiethylene bis(3,4-epoxycyclohexanecarboxylate), 1,4-cyclohexanedimethyl bis(3,4-epoxycyclohexanecarboxylate), and 3-(3,4-epoxycyclohexylmethoxycarbonyl)propyl 3,4-epoxycyclohexanecarboxylate. These may be used alone or as a mixture thereof. Among these bifunctional alicyclic epoxy compounds, 3,4-epoxycyclohexylmethyl 3,4-epoxycyclohexanecarboxylate may be used in some embodiments.

The bifunctional alicyclic epoxy compound may be present in an amount of 5 parts by weight to 30 parts by weight, for example, 5, 6, 7, 8, 9, 10, 11, 12, 13, 14, 15, 16, 17, 18, 19, 20, 21, 22, 23, 24, 25, 26, 27, 28, 29, 30 parts by weight, 5 parts by weight to 25 parts by weight, or 10 parts by weight to 20 parts by weight, relative to 100 parts by weight of the curable compound, for example, the epoxy compound (A). Within any of these ranges, the first bonding layer may allow for initial bonding through rapid (or suitable) initial curing reaction, thereby preventing or reducing the risk of failure even in a high-speed process (e.g., a relatively fast manufacturing process). Furthermore, reaction of the bifunctional aromatic epoxy compound and the bifunctional aliphatic epoxy compound can be promoted by reaction heat caused by curing, thereby facilitating realization of the effects of the present disclosure.

The bifunctional aromatic epoxy compound can further (e.g., more effectively) increase peel strength between the polarizer (and/or protective layer) and the retardation layer having a light transmittance of 1.0% or less in the UVA wavelength range, than a monofunctional aromatic epoxy compound.

In one or more embodiments, the bifunctional aromatic epoxy compound may include a diglycidyl ether compound. The diglycidyl ether compound may be useful or suitable to provide the effects of the present disclosure in an adhesive composition.

For example, the bifunctional aromatic epoxy compound may include at least one selected from among diglycidyl ether of bisphenol A, diglycidyl ether of bisphenol F, and propylene oxide of bisphenol A.

For example, the bifunctional aromatic epoxy compound may be present in an amount of 5 parts by weight to 60 parts by weight, for example, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60 parts by weight, 10 parts by weight to 60 parts by weight, or 15 parts by weight to 50 parts by weight, relative to 100 parts by weight of the curable compound, for example, the epoxy compound (A). Within any of these ranges, the bifunctional aromatic epoxy compound can be useful or suitable in increasing peel strength between the polarizer and the retardation layer having a light transmittance of 1.0% or less in the UVA wavelength range, and/or between the protective layer and the retardation layer.

The bifunctional aliphatic epoxy compound may have characteristics of a long induction period due to stabilization caused by hydrogen bonding with adjacent oxygen atoms after protonation of an epoxy ring by a cation. The bifunctional aliphatic epoxy compound may allow post-reaction after a long induction period. This reaction can provide effects, such as increased peel strength and/or improvement in reliability under high temperature/humidity conditions.

According to some embodiments, the bifunctional aliphatic epoxy compound can further or better (e.g., more effectively) increase peel strength between the polarizer (and/or protective layer) and the retardation layer having a light transmittance of 1.0% or less in the UVA wavelength range than a monofunctional aliphatic epoxy compound.

In one or more embodiments, the bifunctional aliphatic epoxy compound may include a diglycidyl ether compound. The diglycidyl ether compound can effectively or suitably provide or achieve the effects of the present disclosure in adhesive compositions.

For example, the bifunctional aliphatic epoxy compound may include at least one selected from among a diglycidyl ether compound containing a substituted and/or unsubstituted straight and/or branched alkylene group main chain having a carbon number of 3 or more, and a diglycidyl ether compound containing a substituted and/or unsubstituted ethylene oxide and/or propylene oxide therein. Herein, “substituted” refers to at least one hydrogen atom of a corresponding functional group being substituted with a C₁ to C₅ alkyl group. Herein, the carbon number refers to the number of carbon atoms in the main chain of the straight or branched alkylene group.

In one or more embodiments, the bifunctional aliphatic epoxy compound includes the diglycidyl ether compound containing a substituted and/or unsubstituted straight and/or branched alkylene group main chain having a carbon number of 3 or more, which further or better (e.g., more effectively) provides or achieves the effects of the present disclosure than the diglycidyl ether compound having ethylene oxide and/or propylene oxide therein.

The diglycidyl ether compound containing a substituted and/or unsubstituted straight and/or branched alkylene group main chain having a carbon number of 3 or more may have a straight or branched alkylene chain having a carbon number of 3 or more, for example, 3 to 10, or 3 to 6.

For example, the diglycidyl ether compound may include at least one selected from among 1,4-butanediol diglycidyl ether, 1,6-hexanediol diglycidyl ether, trimethylolpropane diglycidyl ether, and neopentyl glycol diglycidyl ether. In one or more embodiments, the diglycidyl ether compound includes neopentyl glycol diglycidyl ether.

In the diglycidyl ether compound containing a substituted and/or unsubstituted ethylene oxide and/or propylene oxide therein, 2 moles or more of ethylene oxide and/or propylene oxide in the diglycidyl ether compound may provide a reaction retardation effect, thereby effectively or suitably providing or achieving the effects of the present disclosure.

The diglycidyl ether compound containing 2 moles or more of ethylene oxide and/or propylene oxide therein may be a diglycidyl ether compound containing 2 to 10 moles of ethylene oxide and/or propylene oxide therein. For example, the diglycidyl ether compound may include at least one of polyethylene glycol diglycidyl ether or polypropylene glycol diglycidyl ether.

The bifunctional aliphatic epoxy compound may be present in an excess amount (e.g., larger amount) in the curable compound relative to each of the bifunctional alicyclic epoxy compound and the bifunctional aromatic epoxy compound. As a result, the polarizing plate can easily or suitably realize the effects of the present disclosure.

For example, the bifunctional aliphatic epoxy compound may be present in an amount of 25 parts by weight to 70 parts by weight, for example 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70 parts by weight, 30 parts by weight to 65 parts by weight, or 35 parts by weight to 60 parts by weight, relative to 100 parts by weight of the curable compound, for example, the epoxy compound (A). Within any of these ranges, the bifunctional aliphatic epoxy compound can be useful or suitable in increasing peel strength between the polarizer and the retardation layer having a light transmittance of 1.0% or less in the UVA wavelength range, and/or between the protective layer and the retardation layer.

### Photoinitiator

The photoinitiator includes the mixture of the iodonium-based photo-acid generator and the anthracene-based photosensitizer, in which the anthracene-based photosensitizer is present in an amount of 0.5 parts by weight or more relative to 100 parts by weight of the curable compound.

The polarizing plate according to the present disclosure includes the photoinitiator in the epoxy compound as the curable compound in order to provide suitably high peel strength between the polarizer (and/or protective layer) and the first retardation layer, for example, a liquid crystal retardation layer, having a light transmittance of 1.0% or less in the UVA wavelength range.

A mixture of an iodonium-based photo-acid generator and a thioxanthone-based photosensitizer and a mixture of a sulfonium-based photo-acid generator and an anthracene-based photosensitizer can secure peel strength and suitable high temperature/humidity reliability under normal (e.g., comparable) UV irradiation conditions. However, in an environment where energy in the UVA region is blocked, such as a liquid crystal layer with negative dispersion, such combinations of a photo-acid generator and a photosensitizer can cause performance degradation, leading to delamination after high temperature/humidity testing and/or significant iodine decolorization from the polarizer.

For example, the mixture of the iodonium-based photo-acid generator and the anthracene-based photosensitizer may provide further delamination and iodine decolorization under high temperature/humidity conditions. Analysis of reaction rate shows that the anthracene-based photosensitizer does not significantly increase a reaction conversion rate of a (meth)acrylic compound and thus allows (e.g., may lead to) insufficient or unsuitable reaction in the final curing reaction, as compared with a thioxanthone-based photosensitizer.

However, for the composition according to the present disclosure, which does not include a (meth)acrylic compound and includes only an epoxy compound as the curable compound, it is believed that, unlike the thioxanthone-based photosensitizer, the anthracene-based photosensitizer minimizes or reduces curing degradation by a negative dispersion liquid crystal retardation layer and consequently exhibits good or suitable results in bonding of the negative dispersion liquid crystal retardation layer.

In one or more embodiments, the iodonium-based photo-acid generator and the anthracene-based photosensitizer may be present in a weight ratio of 3:1 to 10:1, for example, 4:1 to 8:1, (iodonium-based photo-acid generator:anthracene-based photosensitizer). Within this range, the photoinitiator can be useful or suitable in increasing peel strength between the first retardation layer and the polarizer.

Additionally, combination of a sulfonium-based photoinitiator with a relatively long-wavelength absorption region and an anthracene-based photosensitizer may provide (e.g., may lead to) rapid degradation of a curing level due to the negative dispersion liquid crystal retardation layer.

In one or more embodiments, the iodonium-based photo-acid generator may include a diaryliodonium-based photo-acid generator.

The anthracene-based photosensitizer may be present in an amount of 0.5 parts by weight or more relative to 100 parts by weight of the curable compound. When the anthracene-based photosensitizer is present in an amount of 0.5 parts by weight or more, the anthracene-based photosensitizer can be useful or suitable in providing suitably high peel strength by curing the epoxy compound at a relatively high curing rate. For example, the anthracene-based photosensitizer may be present in an amount of 0.5 parts by weight to 6 parts by weight, or 0.5, 1, 1.5, 2, 2.5, 3, 3.5, 4, 4.5, 5, 5.5, 6 parts by weight, 0.5 parts by weight to 3 parts by weight, relative to 100 parts by weight of the curable compound.

The anthracene-based photosensitizer may include an alkoxy group-containing anthracene-based photosensitizer. For example, the anthracene-based photosensitizer may be an anthracene compound represented by Formula 1:

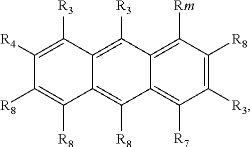

where R₁, R₂, R₃, R₄, R₅, R₆, R₇, R₈, R₉, and Rio may each independently be hydrogen, a substituted or unsubstituted C₁ to C₂₀ alkyl group, a substituted or unsubstituted C₁ to C₂₀ alkoxy group, a substituted or unsubstituted C₁ to C₂₀ mono- or polyalkylenoxy group, a substituted or unsubstituted C₃ to C₂₀ cycloalkyl group, a substituted or unsubstituted C₆ to C₂₀ aryl group, a substituted or unsubstituted C₇ to C₂₀ arylalkyl group, a halogen, a hydroxyl group, an amino group (—NH₂), or a thiol group (—SH), provided that at least one selected from among R₁, R₂, R₃, R₄, R₅, R₆, R₇, R₈, R₉, and Rio is a substituted or unsubstituted C₁ to C₂₀ alkoxy group.

In one or more embodiments, at least two selected from among R₁, R₂, R₃, R₄, R₅, R₆, R₇, R₈, R₉, and Rio may be substituted or unsubstituted C₁ to C₅ alkoxy groups, and the anthracene-based photosensitizer may include a dialkoxy anthracene-based photosensitizer. As used herein, “substituted or unsubstituted” refers to that a hydrogen atom of one or more functional groups is substituted with (e.g., replaced with) a C₁ to C₅ alkyl group, a C₁ to C₅ alkoxy group, a C₆ to C₁₀ aryl group, a C₃ to C₁₀ cycloalkyl group, a halogen, a hydroxyl group, an amino group, and/or the like.

For example, the anthracene-based photosensitizer may include 9,10-dimethoxyanthracene, 9,10-diethoxyanthracene, 9,10-dipropoxyanthracene, 9,10-diisopropoxyanthracene, 9,10-dibutoxyanthracene, 9,10-dipentyloxyanthracene, 9,10-dihexyloxyanthracene, 9,10-bis(2-methoxyethoxy)anthracene, 9,10-bis(2-ethoxyethoxy)anthracene, 9,10-bis(2-butoxyethoxy)anthracene, 9,10-bis(3-butoxypropoxy)anthracene, 2-methyl-9,10-dimethoxyanthracene, 2-ethyl-9,10-dimethoxyanthracene, 2-methyl-9,10-diethoxyanthracene, 2-ethyl-9,10-diethoxyanthracene, 2-methyl-9,10-dipropoxyanthracene, 2-ethyl-9,10-dipropoxyanthracene, 2-methyl-9,10-diisopropoxyanthracene, 2-ethyl-9,10-diisopropoxyanthracene, 2-methyl-9,10-dibutoxyanthracene, 2-ethyl-9,10-dibutoxyanthracene, 2-methyl-9,10-dipentyloxyanthracene, 2-ethyl-9,10-dipentyloxyanthracene, 2-methyl-9,10-dihexyloxyanthracene, 2-ethyl-9,10-dihexyloxyanthracene, and/or the like.

In one or more embodiments, the anthracene-based photosensitizer may be 9,10-dimethoxyanthracene, 9,10-diethoxyanthracene, 9,10-dipropoxyanthracene, 9,10-diisopropoxyanthracene, 9,10-dibutoxyanthracene, 9,10-dipentyloxyanthracene, and/or 9,10-dihexyloxyanthracene, for example, 9,10-dibutoxyanthracene.

The iodonium-based photo-acid generator may include onium salts of iodonium cations and anions. Exemple iodonium cations may include diphenyliodonium, 4-methoxydiphenyliodonium, bis(4-methylphenyl)iodonium, bis(4-tert-butylphenyl)iodonium, bis(dodecylphenyl)iodonium, diaryliodonium, for example (4-methylphenyl)[(4-(2-methylpropyl)phenyl)iodonium, and/or the like. Exemple anions include tetrafluoroborate (BF₄—), hexafluorophosphate (PF₆—), hexafluoroantimonate (SbF₆—), hexafluoroarsenate (AsF₆—), hexachloroantimonate (SbCl₆—), and/or the like. In one or more embodiments, the iodonium-based photo-acid generator is (4-methylphenyl)[(4-(2-methylpropyl)phenyl)iodonium hexafluorophosphate.

The photo-acid generator may be present in an amount of 0.5 parts by weight to 10 parts by weight, for example, 1 part by weight to 6 parts by weight, relative to 100 parts by weight of the curable compound. Within any of these ranges, the adhesive composition can be sufficiently or suitably cured and may not suffer from (e.g., may not be substantially negatively affected by) problems, such as poor bonding strength, bleed-out of a photo-cationic initiator, and/or the like.

In one or more embodiments, the mixture of the iodonium-based photo-acid generator and the anthracene-based photosensitizer may be present in an amount of 80 wt % or more, for example, 80 wt % to 100 wt %, or 100 wt %, relative to 100 wt % of the photoinitiator. Within any of these ranges, the mixture can be useful to increase peel strength between the first retardation layer and the polarizer.

The composition may further include a naphthalene-based photosensitizer as a photosensitizer.

The naphthalene-based photosensitizer may compensate for the lack of photo-initiation response by the anthracene-based photosensitizer. The naphthalene-based photosensitizer may be of any suitable naphthalene-based photosensitizer in the art. The naphthalene-based photosensitizer may be present in an amount of 0.5 parts by weight or more, for example, 0.5 parts by weight to 6 parts by weight, or 1 part by weight to 6 parts by weight, relative to 100 parts by weight of the curable compound. Within any of these ranges, the naphthalene-based photosensitizer can easily or suitably supplement deficient photo-initiation reaction.

In the composition, the photo-acid generator and the photosensitizer, that is, the photoinitiator, may be present in a total amount of 2 parts by weight or more, for example, 3 parts by weight to 10 parts by weight, relative to 100 parts by weight of the curable compound.

The composition may be prepared by mixing the curable compound and the photoinitiator. The composition may be solvent-free or may further include a solvent to increase applicability (coatability).

The composition may further include antioxidants, UV absorbents, ionic conductors, conductivity-imparting additives, such as conductive metal oxide particulates, light diffusivity-imparting additives, viscosity modifiers, and/or the like so long as the additives do not impair (e.g., do not substantially impair) the effects of the present disclosure.

The cured product of the composition, for example, the first bonding layer, may have a glass transition temperature of 30° C. to 150° C., for example, 50° C. to 120° C. Within any of these ranges, the cured product can prevent or reduce delamination upon cutting and generation of cracks under thermal shock conditions.

The first bonding layer may be formed by photo-curing of the composition. Photo-curing may be performed by any suitable method in the art.

The first bonding layer may have a thickness of 1.0 μm to 6.0 μm, for example, 2.0 μm to 5.0 μm. Within any of these ranges, the first bonding layer can be used in a polarizing plate.

### Polarizer

The polarizer serves to polarize external or internal light.

The polarizer may include a polyvinyl alcohol-based polarizer obtained by dyeing a polyvinyl alcohol film with iodine and/or the like. For example, the polyvinyl alcohol-based polarizer may be manufactured by dyeing a polyvinyl alcohol film with iodine and/or a dichroic dye, followed by stretching the dyed film in a set or certain direction. For example, the polarizer is produced through swelling, dyeing, and stretching steps. A method of performing each step (e.g., act or task) should be readily understood by those skilled in the art.

The polarizer may have a thickness of 1 μm to 50 μm. Within this range, the polarizer can be used in an optical display apparatus.

The polarizing plate may further include a protective layer on at least one surface of the polarizer. The protective layer of the polarizing plate may be composed of a single layer or a plurality of layers.

### Protective Layer

The protective layer may be formed on at least one surface of the polarizer to protect the polarizer and/or to provide an additional function to the polarizing plate.

The protective layer may include at least one of an optically clear protective film or an optically clear protective coating layer.

When the protective layer is of the protective film type or kind, the protective layer may include a protective film formed of an optically clear resin. The protective film may be formed by melt extrusion of the resin. As needed, the resin may be further subjected to a stretching process. The resin may include at least one selected from among cellulose ester resins such as triacetylcellulose and/or the like, cyclic polyolefin resins such as cyclic olefin polymer (COP) and/or the like, polycarbonate resins, polyester resins such as polyethylene terephthalate (PET) and/or the like, polyether sulfone resins, polysulfone resins, polyamide resins, polyimide resins, non-cyclic polyolefin resins, poly(meth)acrylate resins such as poly(methyl methacrylate) and/or the like, polyvinyl alcohol resins, polyvinyl chloride resins, and polyvinylidene chloride resins. In one or more embodiments, the protective film is formed of cyclic polyolefin resins including a cyclic polyolefin and/or the like.

When the protective layer is of the protective coating layer type or kind, the protective layer can have good or suitable properties in terms of adhesion to the polarizer, transparency, mechanical strength, thermal stability, moisture barrier capacity, and/or durability. In one or more embodiments, the protective coating layer as the protective layer may be formed of an actinic radiation-curable resin composition including an actinic radiation-curable compound and a polymerization initiator.

The actinic radiation-curable compound may include at least one selected from among a cationic polymerizable curable compound, a radical polymerizable curable compound, a urethane resin, and a silicone resin. The cationic polymerizable curable compound may be an epoxy compound containing at least one epoxy group therein and/or an oxetane compound containing at least one oxetane ring therein. The radical polymerizable curable compound may be a (meth)acrylic compound containing at least one (meth)acryloyloxy group therein.

The protective layer may further include suitable additives in the art. The additives may include antioxidants, UV absorbents, ionic conductors, conductivity imparting additives such as conductive metal oxide particulates, light diffusivity imparting additives, viscosity modifiers, and/or the like.

The protective layer may have a thickness of 5 μm to 200 μm, for example, 30 μm to 120 μm, 50 μm to 100 μm (the protective film type or kind), or 5 μm to 50 μm (the protective coating layer type or kind). Within any of these ranges, the protective layer can be used in an optical display apparatus.

The protective layer may include a functional coating layer formed on at least one surface thereof, and/or may be subjected to surface treatment. The functional coating layer may include a hard coating layer, an anti-fingerprint layer, an antireflection layer, a low reflectivity layer, an ultra-low reflectivity layer, and/or an antiglare layer, without being limited thereto. Surface treatment of the protective layer may include corona treatment, without being limited thereto.

The protective layer may be bonded to the polarizer or to an adherend other than the polarizer through a bonding layer. The bonding layer may be formed of a water-based bonding agent and/or a photocurable bonding agent. Details of the water-based bonding agent and the photocurable bonding agent should be readily understood by those skilled in the art.

If (e.g., when) the protective layer is stacked on the polarizer opposite to the first bonding layer, the protective layer may be referred to as an upper protective layer. In this case, the upper protective layer may include a UV absorbent. The UV absorbent can prevent or reduce damage by external light to optical devices, for example, light emitting devices, in an optical display panel.

In one or more embodiments, the upper protective layer may have a light transmittance of 50% or less, for example, 30% or less, at a wavelength of 380 nm. Within any of these ranges, the upper protective layer can sufficiently or suitably prevent or reduce damage to light emitting devices by external light.

The polarizing plate may further include a second retardation layer. The second retardation layer of the polarizing plate may be composed of a single layer or a plurality of layers.

### Second Retardation Layer

The second retardation layer serves to prevent or reduce reflection of external light having passed through the polarizer by circularly polarizing linearly polarized light emitted from the polarizer, thereby providing an antireflection function to improve external appearance and/or screen quality.

In one or more embodiments, the second retardation layer may have an in-plane retardation of 100 nm to 220 nm, for example, 100 nm to 180 nm, for example, a retardation of λ/4, at a wavelength of 550 nm. Within any of these ranges, the second retardation layer can improve screen quality by reducing reflectivity to external light.

The second retardation layer may have different in-plane retardation at a wavelength of 550 nm than the first retardation layer. A polarizing plate including two retardation layers with different in-plane retardations may have a better (or improved) antireflection effect than a polarizing plate including a single retardation layer.

In one or more embodiments, the second retardation layer may have an in-plane retardation of 225 nm to 350 nm, for example, 225 nm to 300 nm, for example, a retardation of λ/2, at a wavelength of 550 nm. Within any of these ranges, the second retardation layer can improve screen quality by reducing reflectivity to external light.

In one or more embodiments, the second retardation layer may be a positive C retardation layer (nz>nx=ny). For example, the second retardation layer may have a negative out-of-plane retardation of, for example, −200 nm to −10 nm (e.g., −200 nm and −10 nm) at a wavelength of 550 nm.

The second retardation layer may be a liquid crystal retardation layer or a non-liquid crystal retardation layer.

When the second retardation layer is the liquid crystal retardation layer, the second retardation layer may be formed of substantially the same or similar composition to the composition for the first liquid crystal retardation layer of the present embodiments. When the second retardation layer is the non-liquid crystal retardation layer, the second retardation layer may be a coating layer or film formed of an optically clear non-liquid crystalline material.

The second retardation layer may have a thickness of 0.1 μm to 40 μm, for example, 1 μm to 5 μm, or 10 μm to 30 μm. Within any of these ranges, the second retardation layer can provide desired or suitable retardation while allowing reduction in thickness of the polarizing plate.

The polarizing plate may further include a second bonding layer.

### Second Bonding Layer

The second bonding layer may be arranged on a lower surface of the polarizer and may serve to bond the first retardation layer and the second retardation layer to each other.

In one or more embodiments, the second bonding layer may include a cured product of a suitable water-based bonding agent and/or a suitable photo-curable bonding agent in the art. The water-based bonding agent may include an aqueous solvent, a polyvinyl alcohol resin, and a crosslinking agent. The photo-curable bonding agent may include an epoxy compound, a (meth)acrylic compound, and a photoinitiator. The polyvinyl alcohol resin, the crosslinking agent, the epoxy compound, the (meth)acrylic compound, and the photoinitiator may be of any suitable types (kinds) in the art.

For example, the second bonding layer may be formed of the composition including the curable compound and the photoinitiator as described herein in connection with the first bonding layer. As a result, the polarizing plate may have a suitably low variation of light transmittance and good or suitable flexural reliability after being left under high temperature/humidity conditions, and may secure better or improved effects in preventing or reducing generation of cracks in the polarizer after thermal shock and/or minimizing or reducing iodine decolorization after being left under high temperature/humidity conditions.

Descriptions of the curable compound and the photoinitiator are substantially the same as those described above and duplicative descriptions are not provided herein.

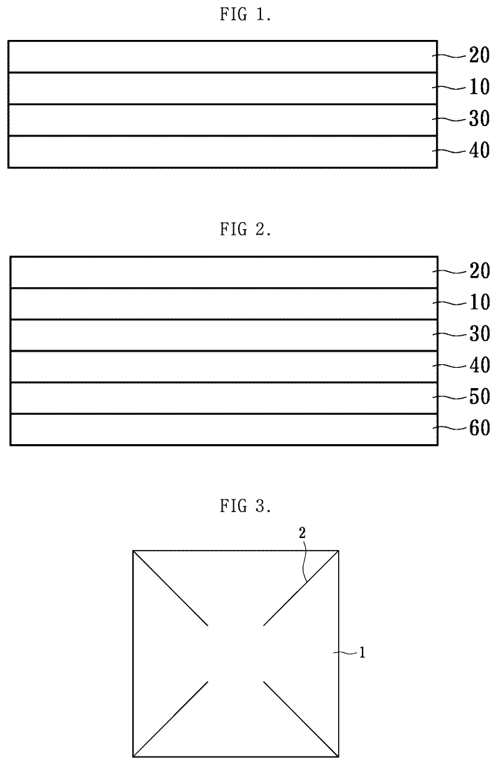

FIG. 1 is a cross-sectional view of a polarizing plate of one or more embodiments of the present disclosure.

Referring to FIG. 1, the polarizing plate according to the one or more embodiments includes a polarizer 10; an upper protective layer 20 stacked on an upper surface of the polarizer 10; and a first bonding layer 30 and a first retardation layer 40 sequentially stacked on a lower surface of the polarizer 10, in which the polarizer 10 may be bonded to the first retardation layer 40 by the first bonding layer 30.

FIG. 2 is a cross-sectional view of a polarizing plate according to one or more other embodiments of the present disclosure.

Referring to FIG. 2, the polarizing plate according to the one or more embodiments may include a polarizer 10; an upper protective layer 20 stacked on an upper surface of the polarizer 10; and a first bonding layer 30, a first retardation layer 40, a second bonding layer 50, and a second retardation layer 60 sequentially stacked on a lower surface of the polarizer 10. The polarizer 10 may be bonded to the first retardation layer 40 by the first bonding layer 30. The first retardation layer 40 may be bonded to the second retardation layer 60 by the second bonding layer 50.

In some embodiments, a functional coating layer, such as a hard-coating layer, a moisture-resistant layer, an antireflection layer, and/or the like, may be further formed on an upper surface of the upper protective layer 20.

In some embodiments, if (e.g., when) the upper protective layer 20 is of a protective film type or kind, a bonding layer may be further formed between the protective layer and the polarizer.

In some embodiments, the polarizing plate may further include at least one selected from among a polarizer protection film, antireflection film, a retardation film (a liquid crystal layer or a non-liquid crystal layer), and an adhesive film suitable for use in polarizing plates.

Hereinafter, a method for manufacturing a polarizing plate according to one or more embodiments will be described.

The manufacturing method may include: preparing a laminate of an upper protective layer and a polarizer, forming a coat for a first bonding layer by applying a composition for the first bonding layer to one surface of a film for a liquid crystal retardation layer, attaching the coat for the first bonding layer to one surface of the laminate, for example, one surface of the polarizer, emitting (e.g., irradiating) UV light towards the laminate from a side of the film for the liquid crystal retardation layer, and transferring the liquid crystal retardation layer by peeling off a base film of the film for the liquid crystal retardation layer.

UV irradiation to form the first bonding layer may include irradiation with light in the UVA wavelength range at a dose of 500 mJ/cm² to 1,000 mJ/cm² for 10 sec to 60 sec.

An optical display apparatus according to one or more embodiments of the present disclosure includes the polarizing plate according to the present disclosure. For example, the optical display apparatus may include a light emitting diode display including light emitting diodes, a liquid crystal display, and/or the like.

Next, the present disclosure will be described in more detail with reference to some examples. However, it should be noted that these examples are provided for illustration only and are not to be construed in any way as limiting the present disclosure.

### Example 1

### (1) Preparation of Adhesive Composition for First Bonding Layer

A total of 100 parts by weight of an epoxy compound was prepared by mixing 12.5 parts by weight of a bifunctional alicyclic epoxy compound (A), 37.5 parts by weight of a bifunctional aromatic epoxy compound (B1), and 50 parts by weight of a bifunctional aliphatic epoxy compound (D). A solvent-free composition was prepared by mixing the epoxy compound with 4 parts by weight of an iodonium-based photo-acid generator (G) and 1 part by weight of an anthracene-based photosensitizer (1). The composition was free from a (meth)acrylate compound.

### (2) Preparation of Polarizing Plate

A polyvinyl alcohol film (degree of polymerization: 2,800, pre-stretching thickness: 30 μm, PE30, Mitsubishi Chemical) was dipped in an aqueous solution containing 0.3 wt % of iodine for dyeing treatment and was uniaxially stretched to 5.0 times an initial length thereof in the MD(machine direction). The stretched polyvinyl alcohol film was dipped in an aqueous solution containing 3 wt % of boric acid and 2 wt % of potassium iodide for color correction, and dried at 50° C. for 4 minutes, thereby preparing a polarizer (light transmittance: 45%, thickness: 7 μm)

As an upper polarizer protection film, a cyclic olefin polymer film (thickness: 25 μm, containing UV absorbent, Zeon) with a hard coating layer formed on an upper surface thereof was prepared, followed by subjecting a lower surface of the film to corona treatment using a corona treatment machine (AFS Entwicklungs+Vertriebs GmbH (AFS)) at a rate of 10 mpm and an output power of 1,000 W.

As a lower polarizer protection film, a triacetylcellulose film (thickness: 40 μm, Normal TAC) was prepared without saponification.

An acetoacetyl group-containing polyvinyl alcohol resin (average degree of polymerization: 1,200; degree of saponification: 98.5 mol %; degree of acetoacetylation: 5 mol %; Z200, Mitsubishi Chemical) was dissolved in water at 95° C. for 60 minutes and then cooled completely at room temperature, thereby preparing an aqueous solution of the polyvinyl alcohol resin. Thereafter, 0.1 wt % of a crosslinking agent (Zircosol-ZN, Daiichi Kigenso Kagaku Kogyo Co., Ltd.) was added to and mixed with the prepared aqueous solution of the polyvinyl alcohol resin, thereby preparing a water-based bonding agent.

After the prepared water-based bonding agent was deposited to a set or predetermined thickness on both (e.g., simultaneously) surfaces (e.g., opposite surfaces) of the polarizer (e.g., to form a bonding layer), the upper polarizer protection film and the lower polarizer protection film were attached to one surface of the polarizer and the other surface of the polarizer, respectively, and were dried at 80° C. for 3 minutes, followed by removing the lower polarizer protection film to prepare a laminate for the polarizing plate.

As a film for a first liquid crystal retardation layer, a film including an alignment layer and a liquid crystal retardation layer (λ/4 retardation at a wavelength of 550 nm, negative dispersion, light transmittance in the UVA region: 0.5%, containing an aromatic group, thickness: 2 μm, Dai Nippon Printing Co., Ltd. (DNP)) sequentially formed on an upper surface of a polyethylene terephthalate (PET) film (thickness: 80 μm, light transmittance in the UVA region: 80%) was prepared. The liquid crystal retardation layer was subjected to corona treatment using a corona treatment machine (AFS) at a rate of 10 mpm and an output power of 1,000 W.

The adhesive composition for the first bonding layer was deposited to a thickness of about 3 μm on the corona-treated surface of the liquid crystal retardation layer and then attached to the surface of the laminate for the polarizing plate, from which the lower polarizer protection film was removed. Thereafter, photocuring was performed through irradiation with UVA from the PET film side towards the liquid crystal retardation layer at a dose of 1,000 mJ/cm² using a metal halide lamp, followed by removal of the PET film, thereby preparing a polarizing plate having a stack structure in which the upper polarizer protection film, the bonding layer, the polarizer, the first bonding layer, the first liquid crystal retardation layer and the alignment layer are sequentially stacked in the stated order.

### Examples 2 to 4

Adhesive compositions and polarizing plates were prepared in substantially the same manner as in Example 1 except that, in preparation of 100 parts by weight of the epoxy compound in the adhesive composition for the first bonding layer, the type or kind and/or content (e.g., amount) of each component was changed as listed in Table 1 and the type or kind and/or content (e.g., amount) of each component of the photo-acid generator and the photosensitizer was changed as listed in Table 1. In the following Table 1, “−” refers to a corresponding component not being present.

### Comparative Examples 1 to 9

Adhesive compositions and polarizing plates were prepared in substantially the same manner as in Example 1 except that, in preparation of 100 parts by weight of the epoxy compound in the adhesive composition for the first bonding layer, the type or kind and/or content (e.g., amount) of each component was changed as listed in Table 1 and the type or kind and/or content (e.g., amount) of each component of the photo-acid generator and the photosensitizer was changed as listed in Table 1. In the following Table 1, “−” refers to a corresponding component not being present.

Each of the polarizing plates prepared in Examples and Comparative Examples was evaluated as to properties listed in Table 2. Results are shown in Table 2.

(1) Decolorization after Exposure to High Temperature/Humidity Conditions

Each of the polarizing plates manufactured in Examples and Comparative Examples was cut to a square size of 25 mm×25 mm with a light absorption axis of the polarizer tilted at an angle of 45°, and then attached to a glass plate via an adhesive layer, thereby preparing a specimen. The specimen was left in a chamber at 60° C. and 95% relative humidity (RH) for 500 hours and then removed from the chamber. Thereafter, a length 2 along which disappearance of iodine color occurred in the specimen 1 was measured diagonally from four corners of the specimen, as shown in FIG. 3, followed by evaluation according to the following criteria:
⊚: Less than 0.5 mm,
∘: Greater than or equal to 0.5 mm and less than 1 mm
Δ: Greater than or equal to 1 mm and less than 3 mm
x: Greater than 3 mm

### (2) Transfer Rate of Negative Dispersion Liquid Crystal Retardation Layer

According to the method described in Examples and Comparative Examples, a specimen was prepared by depositing the adhesive composition for the first bonding layer to a thickness of about 3 μm on the corona-treated surface of the liquid crystal retardation layer, followed by attaching the first bonding layer to the surface of the laminate for the polarizing plate, from which the lower polarizer protection film was removed. The prepared specimen was placed in a curing machine and irradiated with UV light from the liquid crystal retardation layer side to cure the first bonding layer. Here, UV irradiation was performed using a metal halide lamp with UVA at a dose shown in Table 2. After a certain or set period of time from a reference time (0 seconds) if (e.g., when) the specimen was taken out of the curing machine, the base film of the film for the liquid crystal retardation layer was removed by hand at once. The transfer rate of the liquid crystal retardation layer was evaluated by evaluating whether the liquid crystal retardation layer was completely peeled off without remaining on the base film upon removal of the base film.

The transfer rate of the liquid crystal retardation layer could be checked based on reflection visibility if (e.g., when) the polarizing plate was applied to an optical display apparatus. To this end, the polarizing plate was arranged on the optical display apparatus such that the upper protective layer was placed on top, and was irradiated with external light to calculate a ratio of an area appearing black due to an antireflection function to the total area of the polarizing plate. A higher ratio indicated a higher transfer rate of the liquid crystal retardation layer and higher peel strength between the polarizer and the liquid crystal retardation layer.

### (3) Reaction Conversion Rate

The composition for the first bonding layer prepared in each of Examples and Comparative Examples was deposited to a thickness of 3 μm between the polarizer and one surface of the COP film. The other surface of the COP film was partially covered with the film for the first liquid crystal retardation layer prepared in each of Examples and Comparative Examples. Then, the entire surface of the COP film was irradiated with UV light under set or predetermined conditions (UVA reference dose: 1,000 mJ/cm², 1 hour), and UV light transmitting and non-transmitting regions on the surface of the liquid crystal retardation layer were marked, followed by calculating the reaction conversion rate using Fourier transform infrared (FT-IR) after removal of the COP film.

TABLE 1

| | | | | | | | Acrylate | | Photo-acid | | | | | |
|---|---|---|---|---|---|---|---|---|---|---|---|---|---|---|
| | Epoxy compound | | | | | | compound | | generator | | Photosensitizer | | | Initiator |
| | A | B1 | B2 | B3 | C | D | E | F | G | H | I | J | K | L |
| Example 1 | 12.5 | 37.5 | — | — | — | 50 | — | — | 4 | — | 1 | — | — | — |
| Example 2 | 12.5 | 37.5 | — | — | — | 50 | — | — | 4 | — | 0.5 | 1 | — | — |
| Example 3 | 12.5 | — | 37.5 | — | — | 50 | — | — | 4 | — | 1 | — | — | — |
| Example 4 | 12.5 | — | — | 37.5 | — | 50 | — | — | 4 | — | 1 | — | — | — |
| Comparative | 10 | 30 | — | — | — | 40 | 10 | 10 | 4 | — | — | — | 1 | — |
| Example 1 | | | | | | | | | | | | | | |
| Comparative | 10 | 30 | — | — | — | 40 | 10 | 10 | 4 | — | — | — | 1 | 1 |
| Example 2 | | | | | | | | | | | | | | |
| Comparative | 10 | 30 | — | — | — | 40 | 10 | 10 | 4 | — | 1 | — | — | — |
| Example 3 | | | | | | | | | | | | | | |
| Comparative | 10 | 30 | — | — | — | 40 | 10 | 10 | — | 6 | 1 | — | — | — |
| Example 4 | | | | | | | | | | | | | | |
| Comparative | 12.5 | 37.5 | — | — | — | 50 | — | — | 4 | — | — | | 1 | — |
| Example 5 | | | | | | | | | | | | | | |
| Comparative | 12.5 | 37.5 | — | — | — | 50 | — | — | 4 | — | 0.2 | 1 | — | — |
| Example 6 | | | | | | | | | | | | | | |
| Comparative | 12.5 | — | — | — | 37.5 | 50 | — | — | 4 | — | 1 | — | — | — |
| Example 7 | | | | | | | | | | | | | | |
| Comparative | — | 50 | — | — | — | 50 | — | — | 4 | — | 1 | — | — | — |
| Example 8 | | | | | | | | | | | | | | |
| Comparative | 50 | — | — | — | — | 50 | — | — | 4 | — | 1 | — | — | — |
| Example 9 | | | | | | | | | | | | | | |

In Table 1,
A) Multi-functional cycloaliphatic epoxy resin (Celloxide 2021P, Daicel Corporation)
B1) Diglycidyl ether of bisphenol A (YD128, Kookdo Chemical Co., Ltd.)
B2) BPA-PO epoxy resin (EP-4000S, Adeka)
B3) Diglycidyl ether of bisphenol F (YDF170, Kookdo Chemical Co., Ltd.)
C) Dicyclopentadienyl dimethanol epoxy resin (EP-4088S, Adeka)
D) Neopentyl glycol diglycidyl ether (LD203, Kookdo Chemical Co., Ltd.)
E) 4-Hydroxy butyl acrylate (4-HBA, Osaka Organic Chemical Co., Ltd.)
F) Phenoxy ethyl acrylate (M140, Miwon Specialty Chemical Co., Ltd.)
G) lodonium (4-methylphenyl)[4-(2-methylpropyl)phenyl]-, hexafluorophosphate(1-) (Irgacure 250, BASF)
H) Diphenyl-4-(phenylthio)phenyl sulfonium hexafluoroantimonate (CPI-101A, San-Apro)
I) Anthracene photosensitizer (UVS-1331, Kawasaki Kasei)
J) Naphthalene photosensitizer (UVS-2171, Kawasaki Kasei)
K) 2,4-Diethylthioxanthone (DETX-S, Nippon Kayaku)
L) Phosphine oxide type or kind PI (Omnirad 819, IGM Resins)

TABLE 2

| | | | | | | Reaction conversion rate | | | |
|---|---|---|---|---|---|---|---|---|---|
| | | | | | | Non-transmission | | Transmission | |
| | | | Decolorization | | | region of liquid | | region of liquid | |
| | | Peeling | under high | Transfer | | crystal layer | | crystal layer | |
| | Dose | Time | temperature/ | rate | | Epoxy | Acrylic | Epoxy | Acrylic |
| | (mJ/cm²) | (seconds) | humidity | (%) | Remarks | compound | compound | compound | compound |
| Example 1 | 500 | 30 | ⊚ | 80 | — | 82 | — | 80 | — |
| Example 2 | 500 | 60 | ⊚ | 80 | — | 83 | — | 81 | — |
| Example 3 | 500 | 30 | ⊚ | 80 | — | 79 | — | 81 | — |
| Example 4 | 500 | 30 | ⊚ | 80 | — | 81 | — | 82 | — |
| Comparative | 500 | 300 | ◯ | 0 | — | 69 | 86 | 68 | 69 |
| Example 1 | | | | | | | | | |
| Comparative | 500 | 60 | ◯ | 0 | — | 63 | 89 | 61 | 76 |
| Example 2 | | | | | | | | | |
| Comparative | 500 | 60 | Δ | 0 | — | 73 | 90 | 79 | 60 |
| Example 3 | | | | | | | | | |
| Comparative | 1000 | 60 | — | 0 | Uncured | 66 | 97 | 44 | 90 |
| Example 4 | | | | | | | | | |
| Comparative | 500 | 60 | Δ | 0 | — | 79 | — | 81 | — |
| Example 5 | | | | | | | | | |
| Comparative | 1000 | 60 | — | 0 | Uncured | 20 | — | 20 | — |
| Example 6 | | | | | | | | | |
| Comparative | 1000 | 60 | — | 0 | Liquid | 62 | — | 63 | — |
| Example 7 | | | | | crystal | | | | |
| | | | | | non- | | | | |
| | | | | | transfer | | | | |
| Comparative | 1000 | 60 | X | 0 | Poor | 75 | — | 77 | — |
| Example 8 | | | | | curing | | | | |
| Comparative | 1000 | 60 | — | 0 | Liquid | 71 | — | 69 | — |
| Example 9 | | | | | crystal | | | | |
| | | | | | non- | | | | |
| | | | | | transfer | | | | |

As shown in Table 2, the polarizing plates of Examples could sufficiently or suitably prevent or reduce penetration of iodine eluted from the polarizer into the retardation layer after being left under high temperature/humidity conditions for a long period of time. The polarizing plates of Examples had suitably high transfer rates and suitably high reaction conversion rates, thereby providing suitably high peel strength between the polarizer and the retardation layer having a light transmittance of 1.0% or less in the UVA wavelength range, and/or between the protective layer and the retardation layer.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It should be understood that one or more suitable modifications, changes, alterations, and equivalent embodiments may be made by those skilled in the art without departing from the spirit and scope of the disclosure as defined by the following claims and their equivalents.

What is claimed is:

1. A polarizing plate comprising:
a polarizer; and
a first bonding layer and a first retardation layer sequentially stacked on a lower surface of the polarizer,
wherein the first retardation layer has a light transmittance of 1.0% or less in a UVA wavelength range,
wherein the first bonding layer comprises a cured product of a non-(meth)acrylic composition comprising a curable compound and a photoinitiator,
wherein the curable compound comprises an epoxy compound (A), the epoxy compound (A) comprising a mixture of a bifunctional alicyclic epoxy compound, a bifunctional aromatic epoxy compound, and a bifunctional aliphatic epoxy compound, and
wherein the photoinitiator comprises a mixture of an iodonium-based photo-acid generator and an anthracene-based photosensitizer, the anthracene-based photosensitizer being present in an amount of 0.5 parts by weight or more relative to 100 parts by weight of the curable compound.

2. The polarizing plate as claimed in claim 1, wherein the first retardation layer is a negative dispersion liquid crystal retardation layer.

3. The polarizing plate as claimed in claim 1, wherein the bifunctional alicyclic epoxy compound, the bifunctional aromatic epoxy compound, and the bifunctional aliphatic epoxy compound are present in a total amount of 95 parts by weight or more relative to 100 parts by weight of the epoxy compound (A).

4. The polarizing plate as claimed in claim 1, wherein the bifunctional aliphatic epoxy compound is present in a larger amount in the curable compound relative to each of the bifunctional alicyclic epoxy compound and the bifunctional aromatic epoxy compound.

5. The polarizing plate as claimed in claim 1, wherein the bifunctional aromatic epoxy compound comprises at least one selected from among diglycidyl ether of bisphenol A, diglycidyl ether of bisphenol F, and propylene oxide of bisphenol A.

6. The polarizing plate as claimed in claim 1, wherein the bifunctional aliphatic epoxy compound comprises at least one selected from among a diglycidyl ether compound containing a substituted or unsubstituted straight or branched alkylene group main chain having a carbon number of 3 or more and a diglycidyl ether compound containing a substituted or unsubstituted ethylene oxide or propylene oxide therein.

7. The polarizing plate as claimed in claim 1, wherein the bifunctional alicyclic epoxy compound is present in an amount of 5 parts by weight to 30 parts by weight, the bifunctional aromatic epoxy compound is present in an amount of 5 parts by weight to 60 parts by weight, and the bifunctional aliphatic epoxy compound is present in an amount of 25 parts by weight to 70 parts by weight, relative to 100 parts by weight of the epoxy compound (A).

8. The polarizing plate as claimed in claim 1, wherein the iodonium-based photo-acid generator and the anthracene-based photosensitizer are present in a weight ratio of 3:1 to 10:1 (iodonium-based photo-acid generator:anthracene-based photosensitizer).

9. The polarizing plate as claimed in claim 1, wherein the iodonium-based photo-acid generator is a diaryliodonium-based photo-acid generator.

10. The polarizing plate as claimed in claim 1, wherein the anthracene-based photosensitizer is a dialkoxyanthracene-based photosensitizer.

11. The polarizing plate as claimed in claim 1, wherein the mixture of the iodonium-based photo-acid generator and the anthracene-based photosensitizer is present in an amount of 80 wt % or more in the photoinitiator relative to 100 wt % of the photoinitiator.

12. The polarizing plate as claimed in claim 1, wherein the non-(meth)acrylic composition further comprises a naphthalene-based photosensitizer.

13. The polarizing plate as claimed in claim 1, further comprising: a protective layer on an upper surface of the polarizer.

14. The polarizing plate as claimed in claim 13, wherein the protective layer comprises a UV absorbent.

15. The polarizing plate as claimed in claim 14, wherein the protective layer has a light transmittance of 50% or less at a wavelength of 380 nm.

16. An optical display apparatus comprising the polarizing plate as claimed in claim 1.
